(19) United States
(12) Patent Application Publication
(10) Pub. No.: US 2017/0090294 A1
(43) Pub. Date: Mar. 30, 2017

(54) High-volume replication of diffractive optical elements

(71) Applicant: Apple Inc., Cupertino, CA (US)

(72) Inventors: Moshe Kriman, Herzliya Pituah (IL); Zafrir Mor, Herzliya Pituah (IL)

(21) Appl. No.: 14/868,410

(22) Filed: Sep. 29, 2015

(51) Int. Cl. G03F 7/20

(52) U.S. Cl. CPC G03F 7/70

(57) ABSTRACT

A method for manufacturing includes forming on a surface of a metal master a pattern that defines an array of diffractive optical elements (DOEs). The pattern is replicated from the metal master onto a layer of a curable polymer that is deposited over a transparent substrate. The polymer in which the pattern has been replicated is cured, thereby setting the DOEs in the polymer. The transparent substrate is diced so as to singulate the DOEs.

### FIELD OF THE INVENTION

The present invention relates generally to optical components, and particularly to methods and systems for production of diffractive optical elements (DOEs).

### BACKGROUND

Diffractive optical elements (DOEs) are used in a wide range of optical applications and systems. For example, U.S. Patent Application Publication 2013/0120841 describes the use of DOEs in optical pattern projection. Such DOEs typically contain very fine, precise diffractive structures.

Various methods are known in the art for manufacturing DOEs. For example, U.S. Pat. No. 5,938,989 describes a method for the replication of diffractive optical elements using audio/video disc manufacturing equipment and processes. The manufacturing process and mold mastering tooling create diffractive optical elements using a mold plate. The diffractive optic design and photomasks are first fabricated then replicated using compact disc industry mold mastering techniques. The surface relief pattern is produced centered in the plate using ion milling or refractive ion etching photolithographic fabrication techniques. Once patterned, the mold master plate is punched into a circular form consistent with standard compact or video disc mold bases. After molding, each element can be cut out of the disc using blade, shear, waterjet or laser cutting.

As another example, U.S. Pat. No. 7,658,877 describes manufacturing of a micro-structured element by replicating/shaping (molding or embossing or the like) a 3D-structure in a preliminary product using a replication tool. The replication tool comprises a spacer portion protruding from a replication surface. The replica (the micro-structured element, for example a micro-optical element) may be made of epoxy, which is cured—for example UV cured—while the replication tool is still in place. The replication process may be an embossing process, wherein the deformable or viscous or liquid component of the preliminary product to be shaped is placed on a surface, and then the replication tool is pressed against this surface. As an alternative, the replication process may be a molding process.

Still a further example is presented in PCT International Publication WO 2000/002089, which describes a method of making optical replicas by stamping in photoresist. Optical structures are replicated in photoresist on a substrate using a stamp. The transfer of the pattern into the liquid photoresist and the provision on the substrate can be achieved using manual pressures. The stamp is removed once the liquid photoresist is fully solidified. These structures in solidified photoresist may serve as optical elements or may be accurately transferred into the substrate. The stamp may be for an entire wafer.

### SUMMARY

Embodiments of the present invention that are described hereinbelow provide methods and systems for production of DOEs.

There is therefore provided, in accordance with an embodiment of the invention, a method for manufacturing, which includes forming on a surface of a metal master a pattern that defines an array of diffractive optical elements (DOEs). The pattern is replicated from the metal master onto a layer of a curable polymer that is deposited over a transparent substrate. The polymer in which the pattern has been replicated is cured, thereby setting the DOEs in the polymer. The transparent substrate is diced so as to singulate the DOEs.

Typically, the polymer is selected from a group of polymer materials consisting of resins and epoxies, and curing the polymer includes applying to the substrate at least one form of energy selected from a group consisting of heat and ultraviolet radiation.

In a disclosed embodiment, forming the pattern includes writing the pattern onto a surface layer of a semiconductor substrate, depositing a metal layer over the surface layer into which the pattern has been written, and removing the semiconductor substrate from the metal layer.

Additionally or alternatively, forming the pattern includes producing multiple metal mold elements, each mold element corresponding to a respective one of the DOEs, mounting the multiple metal mold elements on a base in respective positions selected so as to define the array of DOEs, and filling gaps between the metal mold elements on the base with a filler material.

In a disclosed embodiment, forming the pattern includes adding yard structures to the metal master surrounding respective loci of the DOEs in the array.

In some embodiments, replicating the pattern includes transferring the pattern from the metal master to a metal sub-master, and applying the metal sub-master in replicating the pattern. In one embodiment, applying the metal sub-master includes molding the curable polymer by bringing the metal sub-master into contact with the curable polymer.

Additionally or alternatively, replicating the pattern includes transferring the pattern from the metal master to an elastic mold, and molding the curable polymer by bringing the elastic mold into contact with the curable polymer. In one embodiment, the elastic mold includes a silicon-based organic polymer.

In an alternative embodiment, replicating the pattern includes transferring the pattern from the metal master to a thermoplastic stamp, and molding the curable polymer by bringing the thermoplastic stamp into contact with the curable polymer. In a disclosed embodiment, transferring the pattern includes producing the thermoplastic stamp by injecting a thermoplastic polymer into a mold that is made from the metal master.

There is also provided, in accordance with an embodiment of the invention, a system for manufacturing, which includes a mastering station, configured to form on a surface of a metal master a pattern that defines an array of diffractive optical elements (DOEs). A replication station is configured to replicate the pattern from the metal master onto a layer of a curable polymer that is deposited over a transparent substrate, and to cure the polymer in which the pattern has been replicated, thereby setting the DOEs in the polymer. A dicing station is configured to dice the transparent substrate so as to singulate the DOEs.

In a disclosed embodiment, the system includes a patterning station, which is configured to write the pattern onto a surface layer of a semiconductor substrate, wherein the mastering station is configured to produce the metal master by depositing a metal layer over the surface layer into which the pattern has been written and then removing the semiconductor substrate from the metal layer.

Additionally or alternatively, the system includes a molding station, which is configured to transfer the pattern from the metal master to an elastic mold, which is brought into contact with the curable polymer in the replication station in order to replicate the pattern. Alternatively, the molding station is configured to transfer the pattern from the metal master to a thermoplastic stamp, which is brought into contact with the curable polymer in the replication station in order to replicate the pattern.

The present invention will be more fully understood from the following detailed description of the embodiments thereof, taken together with the drawings in which:

### BRIEF DESCRIPTION OF THE DRAWINGS

FIG. 1 is a block diagram that schematically illustrates a system for production of DOEs, in accordance with an embodiment of the invention;

FIG. 2A is a schematic, sectional view of a substrate that has been prepared for patterning, in accordance with an embodiment of the invention;

FIG. 2B is a schematic, sectional view of the substrate of FIG. 2A following patterning of multiple diffractive structures on the substrate, in accordance with an embodiment of the invention;

FIG. 2C is a schematic, sectional view of the patterned substrate of FIG. 2B following plating of a metal layer over the pattern, in accordance with an embodiment of the invention;

FIG. 2D is a schematic, sectional view of a metal master produced by the plating operation of FIG. 2C, in accordance with an embodiment of the invention;

FIG. 2E is a schematic, sectional view of the metal master of FIG. 2D following the formation of yards around the diffractive structures on the master, in accordance with an embodiment of the invention;

FIG. 2F is a schematic, sectional view of a mold substrate with an elastic material thereon, showing molding of the elastic material by the patterned metal master mold of FIG. 2E to produce a working mold, in accordance with an embodiment of the invention;

FIG. 2G is a schematic, sectional view of a production substrate with a curable polymer thereon, showing molding of the curable polymer by the working mold of FIG. 2F, in accordance with an embodiment of the invention; and

FIG. 2H is a schematic, sectional view of the production substrate of FIG. 2G, showing an array of DOEs formed on the production substrate by the molding step illustrated in FIG. 2G, in accordance with an embodiment of the invention;

FIG. 3A is a schematic, sectional view of a base to which an array of master elements has been fixed, in accordance with an alternative embodiment of the invention;

FIG. 3B is a schematic, sectional view of a metal master formed from the array of FIG. 3A, in accordance with an alternative embodiment of the invention;

FIG. 4 is a schematic, sectional view of a thermoplastic stamp, in accordance with another embodiment of the invention; and

FIG. 5 is a schematic, sectional view of a production substrate with a curable polymer thereon, showing an array of DOEs formed on the production substrate by application of a metal sub-master, in accordance with yet another embodiment of the invention.

### DETAILED DESCRIPTION OF EMBODIMENTS

### Overview and System Description

Large-scale manufacturing of DOEs has, up to now, generally been based on injection molding or stamping of thermoplastics, such as polycarbonates. Thermoplastic materials, however, are prone to degradation at elevated temperatures and are difficult to seal against moisture and contaminants. Etched glass DOEs offer much better durability and precision but are too costly for mass-market applications.

In contrast to these methods, DOE replication by molding of curable polymers, such as resins and epoxies, which harden when exposed to ultraviolet radiation or heat, offers a solution that is durable and precise, at much lower cost than etched glass components. The term “molding,” as used in the present description and in the claims, refers broadly to processes in which a pattern is transferred from a master to a target material, which may be liquid, viscous, or otherwise soft enough to be deformed by the mold. In this sense, “molding” includes stamping and embossing processes.

High-volume replication of DOEs in this manner, however, requires accurate working molds, which maintain their accuracy and fidelity through many production cycles. Embodiments of the present invention that are described herein address this need by using metal masters in the replication process. A pattern that defines an array of DOEs is formed on the surface of a metal master, from which the pattern is replicated onto a layer of a curable polymer that is deposited over a transparent substrate, such as glass. The polymer in which the pattern has been replicated is cured, thereby setting the DOEs in the polymer, and the substrate is then diced so as to singulate the DOEs.

The term “replicated,” as used in the present description and in the claims, includes both direct replication, in which the metal master itself serves as the mold for the curable polymer, and indirect replication, in which the pattern is copied in one or more stages from the metal master to a sub-master and/or working mold, which is then applied to the curable polymer. A number of different replication processes of this sort are described hereinbelow.

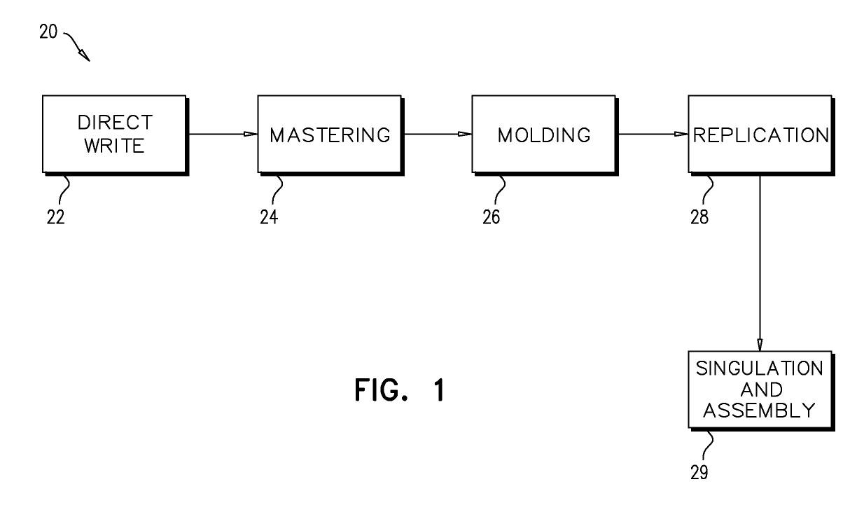

FIG. 1 is a block diagram that schematically illustrates a system 20 for production of DOEs, in accordance with an embodiment of the invention. The stations in system 20 comprise standard fabrication tools, similar to tools that are commercially available and widely used in production processes of microelectronic and micromechanical devices. The modifications needed in these tools to implement the processes described below will be apparent to those skilled in the art after reading the description that follows.

Initially, a pattern that defines the desired DOE profile is written onto a surface layer of a suitable substrate, such as a semiconductor substrate, in a patterning station 22. Station 22 typically comprises a direct laser writing machine or e-beam lithography machine, which writes multiple copies of the DOE pattern into a layer of photoresist on the surface of a semiconductor wafer. Alternatively, multiple copies of the pattern may be created by optical lithography, using a suitable mask and stepper. In either case, the photoresist is then developed, thus creating the desired DOE pattern of ridges and grooves on the surface of the wafer.

In a mastering station 24, the pattern defining the array of DOEs is transferred from the patterned semiconductor wafer to the surface of a metal master. For this purpose, a layer of a suitable metal, such as nickel, is deposited over the surface layer of the wafer, following which the wafer is removed from the metal layer. For example, the patterned wafer may first be covered with a thin metal seed layer by vapor deposition, followed by electroplating of the metal to the full desired thickness of the master. The wafer and remaining photoresist can then be removed, for example, by a chemical etching process, leaving the master in which the pattern from the wafer has been impressed. In this case, it may be useful to deposit an etch-stop layer over the wafer surface before the metal seed layer, in order to protect the metal master from etching. Alternatively, other methods of pattern transfer, as are known in the art, may be used in station 24 to create the metal master from the patterned wafer.

A molding station 26 produces metal sub-masters and working molds from the metal master. Metal sub-masters can be produced, for example, by forming a thin non-conductive layer (such as an oxide layer) on the surface of the metal master, and then plating over the non-conductive layer to form the sub-master as a precise “negative” of the original master. A variety of different types of sub-masters and working molds, as well as techniques used in their production, are described with reference to the embodiments that follow.

A replication station 28 replicates the pattern from the metal master onto a layer of a transparent, curable polymer that is deposited over a transparent substrate, such as a layer of a suitable epoxy or other resin on a glass or acrylic wafer. As noted earlier, this replication typically takes place via a sub-master or working mold that was produced in molding station 26. Different replication techniques are described in the context of the embodiments that follow. The polymer in which the pattern has been replicated is then cured, typically by heating or ultraviolet (UV) exposure, thereby setting the DOEs in the polymer.

The glass wafer on which the array of DOEs has been replicated is passed to a dicing station 29, which dices the transparent substrate so as to singulate the DOEs. The DOEs can be assembled into a desired structure either before or after singulation. For example, in one application, a pair of two different DOEs is coupled together by sealing the DOEs to opposite sides of a spacer layer, with the active (patterned) surfaces of the DOEs facing inward. This arrangement holds the two DOEs in the desired spatial relationship while protecting the active surfaces from environmental contamination. The DOEs may be assembled in this manner after singulation. Alternatively, a pair of suitable DOE wafers, each with an array of DOEs, may be aligned and sealed on opposing sides of a spacer wafer, with openings at the locations of the DOEs, and the entire assembly may then be diced to produce the finished, sealed DOE pairs.

### Embodiment I

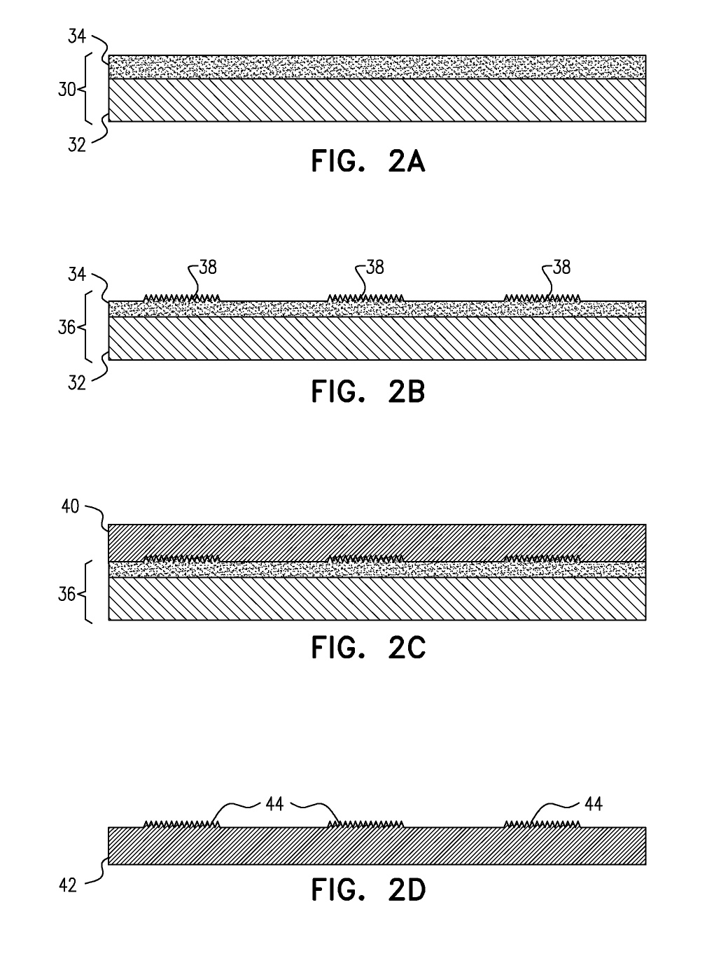

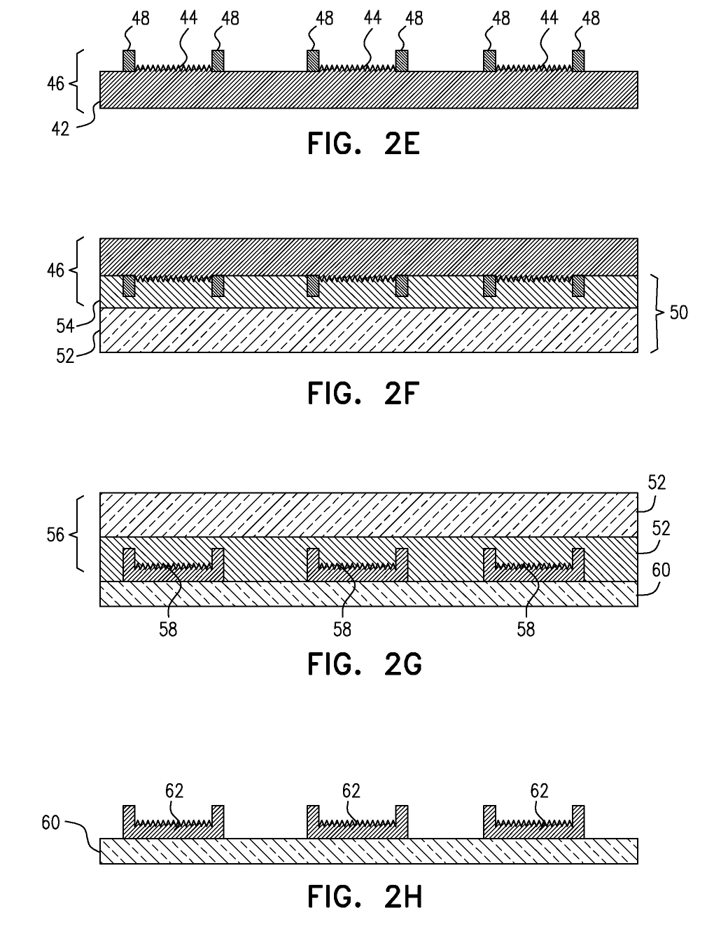

Reference is now made to FIGS. 2A-2H, which are schematic, sectional views showing successive stages in a process for manufacturing DOEs, in accordance with an embodiment of the invention. The following figures and description include, for the sake of completeness, stages of production starting from patterning station 22. These preliminary stages can be implemented in similar fashion in the other embodiments that are described below and are therefore omitted from the other embodiments for the sake of brevity.

In the present embodiment, the DOE pattern is replicated by first transferring the pattern from the metal master to an elastic mold (in molding station 26), and applying this elastic mold to the curable polymer in replication station 28. For example, the elastic mold can comprise a silicon-based organic polymer, such as polydimethylsiloxane (PDMS). This sort of mold is advantageous in that, due to its elasticity, it can easily be released from the DOE surface after molding and curing, without damaging the DOE. On the other hand, such elastic molds tend to degrade in use and lose fidelity when replicated. It is therefore preferable that the elastic mold be formed directly from the metal master or a metal sub-master.

FIG. 2A is a schematic, sectional view of a substrate 30 that has been prepared for patterning. Substrate 30 comprises, for example, a silicon wafer 32 on which a layer of photoresist 34 has been deposited, as is known in the art. FIG. 2B shows a patterned substrate 36, which is producing by patterning of multiple diffractive structures on substrate 30. The patterning is performed in patterning station 22, for example by direct laser writing or e-beam lithography, followed by development of photoresist 34, as described above.

FIG. 2C shows patterned substrate 36 following plating of a metal layer 40, such as a nickel layer, over the pattern of diffractive structures 38. Metal layer 40 thus contains a “negative” of the pattern of structures 38. Removal of patterned substrate 36, by etching for example, leaves a metal master 42, as shown in FIG. 2D, with a pattern that defines an array of DOEs in respective loci 44. This sort of metal master is also referred to as a “shim.” The features (ridges and grooves) of the pattern produced on metal master 42 in this manner may have dimensions on the order of 1 μm or even smaller.

At the stage of actual replication of the DOEs in the curable polymer (shown in FIG. 2G), it is desirable that the locus of each DOE be surrounded by a yard structure for the purpose of material control. This sort of yard structure can be produced, for example, by depositing and then patterning a layer of photoresist or other suitable polymer directly onto master 42. FIG. 2E shows a yarded metal master 46, following the formation of such yards 48 on metal master 42. Yards 48 thus protrude from the surface of master 46 around the diffractive structures at loci 44. Alternatively, the yards may be formed by milling or otherwise machining grooves around loci 44, in which case corresponding yards will protrude in a sub-master or working mold that is made from the master. Although FIG. 2E shows deposition of yards 48 on master 42, the yards may alternatively be added on a metal sub-master that is copied from the original master (or from a previous-generation metal sub-master).

To make an elastic working mold, metal master 46 is brought into contact with and pressed against a molding blank 50, as shown in FIG. 2F. Alternatively, this step may be performed using a metal sub-master in place of master 46. Blank 50 comprises a mold substrate 52, such as a glass or suitable plastic wafer, with a moldable elastic material 54, such as PDMS, on its surface. Molding by master 46 creates a “negative” of the master pattern in material 54, which is cured (typically by heating or other suitable treatment) in order to produce a working mold 56, as shown in FIG. 2G. Working mold 56 is hardened but still elastic.

As shown in FIG. 2G, working mold 56 is pressed against a production substrate 60 with a layer of curable polymer 58 on its surface, such as a suitable epoxy, acrylic, or other resin. Both substrate 60 and polymer 58 are transparent. As noted earlier, substrate 60 typically comprises a wafer made from glass or a suitable plastic, such as polymethyl methacrylate (PMMA) or another acrylic or polycarbonate polymer. Ultraviolet radiation and/or heat is applied through substrate 60 in this configuration in order to cure polymer 58.

When curing has advanced sufficiently, working mold 56 is removed, leaving an array of DOEs 62 formed on the production substrate 60, as shown in FIG. 2H. The DOEs are then singulated by dicing substrate 60, as described above. Optionally, before dicing, an optical coating, such as an anti-reflection coating, and/or other components may be added to the DOE array. Additionally or alternatively, as noted earlier, substrate 60 with DOEs 62 formed on its surface may be bonded to a spacer layer and/or other optical or optoelectronic wafers before dicing.

### Embodiment II

It may be difficult to produce master 42 directly from patterned substrate 36 with sufficient yield (FIGS. 2C-2D). Therefore, in an alternative embodiment, a reconstituted master is formed from multiple metal mold elements with a filler material filled into the gaps in between.

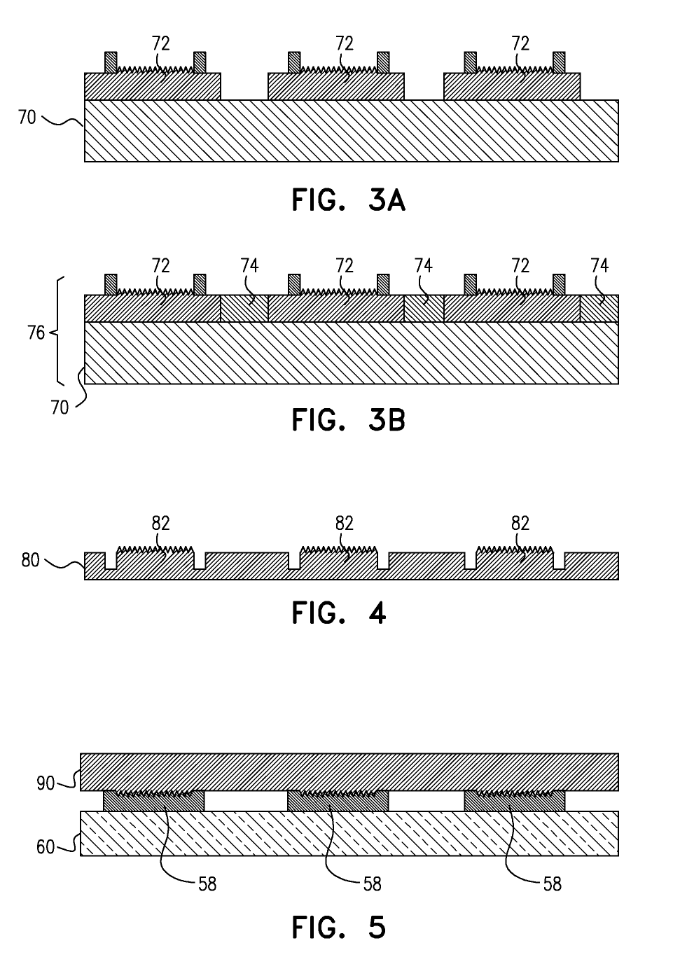

FIG. 3A is a schematic, sectional view of a base 70 to which an array of such master mold elements 72 has been fixed, in accordance with this alternative embodiment of the invention. Each mold element 72 corresponds to a respective one of DOEs 62. Mold elements 72 can be produced, for example, by the steps of the process that is illustrated in FIGS. 2A-2E and described above with reference thereto. At the stage shown in FIG. 2E, yarded metal master 46 is diced in order to singulate metal mold elements 72. The mold elements that are found to be suitable are mounted on base 70 in respective positions selected so as to define the array of DOEs.

FIG. 3B is a schematic, sectional view of a reconstituted metal master 76 that formed from the array of FIG. 3A. The gaps between metal mold elements 72 on base 70 are filled with a suitable filler material 74, such as an epoxy or epoxy-based compound, inserted in the gaps by pressing or molding. Typically, at this stage, reconstituted metal master 76 is used to produce one or more generations of copied metal sub-masters. These sub-masters may then be used in producing an elastic working mold, as described above (FIGS. 2F-2G), or may themselves be applied as molds directly to a production substrate in order to produce DOEs 62 (as shown in FIG. 5).

### Embodiment III

FIG. 4 is a schematic, sectional view of a stamp 80 made from a thermoplastic material, in accordance with another embodiment of the invention. Stamp 80 contains an array of mold elements 82, corresponding in their shapes and locations to the array of DOEs 62 (FIG. 2H), and is used in replication station 28, in place of the working molds described above, in molding the DOEs on production substrate 60. Typically, stamp 80 comprises a suitable thermoplastic material, such as polycarbonate, which is suitable for one-time use in molding DOEs 62 from curable polymer 58, and is then discarded after use. Because of the low cost and simplicity of production of stamp 80, this sort of one-time use is feasible and even advantageous.

Stamp 80 is produced by transferring the pattern of DOEs from a metal master to the thermoplastic, for example by injecting a thermoplastic polymer into a mold that is made from the metal master (such as master 46), either directly or using a sub-master. The metal master can produced as described in either of the preceding embodiments. Curable polymer 58 on production substrate 60 is molded by bringing stamp 80 into contact with the curable polymer, in the manner illustrated in FIG. 2G.

### Embodiment IV

FIG. 5 is a schematic, sectional view of a metal sub-master 90 used as a mold in forming an array of DOEs in curable polymer 58 on production substrate 60, in accordance with yet another embodiment of the invention. Sub-master 90 is produced by transfer of the pattern from a metal master, such as master 46 (which itself is produced as described above and shown in FIGS. 2A-2E). Sub-master 90 may be produced by direct copying of master 46 or by copying via one or more intervening generations of sub-masters. As noted earlier, metal sub-masters can be produced, for example, by forming a thin non-conductive layer (such as an oxide layer) on the surface of the metal master, using wet chemistry or another suitable process. The sub-master is then formed by electro-plating over the non-conductive layer. Because the thickness of the non-conductive layer is in the nanometer range, the sub-master is a precise “negative” of the original master.

In contrast to the preceding embodiments, metal sub-master 90 in this case is brought directly into contact with curable polymer 58 and thus serves as the working mold. This use of a metal working mold is advantageous in accurate DOE replication and in enabling the same mold to be used over many production cycles.

It will be appreciated that the embodiments described above are cited by way of example, and that the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. A method for manufacturing, comprising:
forming on a surface of a metal master a pattern that defines an array of diffractive optical elements (DOEs);
replicating the pattern from the metal master onto a layer of a curable polymer that is deposited over a transparent substrate;
curing the polymer in which the pattern has been replicated, thereby setting the DOEs in the polymer; and
dicing the transparent substrate so as to singulate the DOEs.

2. The method according to claim 1, wherein the polymer is selected from a group of polymer materials consisting of resins and epoxies.

3. The method according to claim 1, wherein curing the polymer comprises applying to the substrate at least one form of energy selected from a group consisting of heat and ultraviolet radiation.

4. The method according to claim 1, wherein forming the pattern comprises:
writing the pattern onto a surface layer of a semiconductor substrate;
depositing a metal layer over the surface layer into which the pattern has been written; and
removing the semiconductor substrate from the metal layer.

5. The method according to claim 1, wherein forming the pattern comprises:
producing multiple metal mold elements, each mold element corresponding to a respective one of the DOEs;
mounting the multiple metal mold elements on a base in respective positions selected so as to define the array of DOEs; and
filling gaps between the metal mold elements on the base with a filler material.

6. The method according to claim 1, wherein forming the pattern comprises adding yard structures to the metal master surrounding respective loci of the DOEs in the array.

7. The method according to claim 1, wherein replicating the pattern comprises transferring the pattern from the metal master to a metal sub-master, and applying the metal sub-master in replicating the pattern.

8. The method according to claim 7, wherein applying the metal sub-master comprises molding the curable polymer by bringing the metal sub-master into contact with the curable polymer.

9. The method according to claim 1, wherein replicating the pattern comprises transferring the pattern from the metal master to an elastic mold, and molding the curable polymer by bringing the elastic mold into contact with the curable polymer.

10. The method according to claim 9, wherein the elastic mold comprises a silicon-based organic polymer.

11. The method according to claim 1, wherein replicating the pattern comprises transferring the pattern from the metal master to a thermoplastic stamp, and molding the curable polymer by bringing the thermoplastic stamp into contact with the curable polymer.

12. The method according to claim 11, wherein transferring the pattern comprises producing the thermoplastic stamp by injecting a thermoplastic polymer into a mold that is made from the metal master.

13. A system for manufacturing, comprising:
a mastering station, configured to form on a surface of a metal master a pattern that defines an array of diffractive optical elements (DOEs);
a replication station, which is configured to replicate the pattern from the metal master onto a layer of a curable polymer that is deposited over a transparent substrate, and to cure the polymer in which the pattern has been replicated, thereby setting the DOEs in the polymer; and
a dicing station, which is configured to dice the transparent substrate so as to singulate the DOEs.

14. The system according to claim 13, wherein the polymer is selected from a group of polymer materials consisting of resins and epoxies and is cured by applying to the substrate at least one form of energy selected from a group consisting of heat and ultraviolet radiation.

15. The system according to claim 13, and comprising a patterning station, which is configured to write the pattern onto a surface layer of a semiconductor substrate, wherein the mastering station is configured to produce the metal master by depositing a metal layer over the surface layer into which the pattern has been written and then removing the semiconductor substrate from the metal layer.

16. The system according to claim 13, wherein the metal master comprises multiple metal mold elements, each mold element corresponding to a respective one of the DOEs, which are mounted on a base in respective positions selected so as to define the array of DOEs, with a filler material filled into gaps between the metal mold elements on the base.

17. The system according to claim 13, wherein the pattern is replicated by transferring the pattern from the metal master to a metal sub-master, and applying the metal sub-master in replicating the pattern.

18. The system according to claim 17, wherein the curable polymer is molded in the replication station by bringing the metal sub-master into contact with the curable polymer.

19. The system according to claim 13, and comprising a molding station, which is configured to transfer the pattern from the metal master to an elastic mold, which is brought into contact with the curable polymer in the replication station in order to replicate the pattern.

20. The system according to claim 13, and comprising a molding station, which is configured to transfer the pattern from the metal master to a thermoplastic stamp, which is brought into contact with the curable polymer in the replication station in order to replicate the pattern.
